(19) United States
(12) Patent Application Publication
(10) Pub. No.: US 2010/0120222 A1
(43) Pub. Date: May 13, 2010

(54) Methods and apparatus for bonding wafers

(75) Inventor: Yu-Sik Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/590,376

(22) Filed: Nov. 6, 2009

(30) Foreign Application Priority Data
Nov. 10, 2008 (KR) 10 2008 0111065

(51) Int. Cl. H01L 21/30

(52) U.S. Cl. 438/455; 257/E21.211

(57) ABSTRACT

In a method of and apparatus for bonding wafers, the method includes heating a first wafer having a first coefficient of thermal expansion (CTE) until the first wafer reaches a first temperature, heating a second wafer having a second CTE that is different from the first CTE until the second wafer reaches a second temperature that is different from the second temperature, and bonding the first wafer and the second wafer to each other.

This application claims priority from Korean Patent Application No. 10-2008-0111065 filed on Nov. 10, 2008 in the Korean Intellectual Property Office, the disclosure of which is incorporated herein by reference in its entirety.

### BACKGROUND

1. Field

Embodiments of the present invention relate to a method and apparatus for bonding wafers.

2. Description of the Related Art

A wafer bonding process for bonding two wafers to each other is commonly employed in the manufacture of semiconductors. When two wafers having different coefficients of thermal expansion (CTE) are bonded to each other, the wafers may become exposed to tensile stress or compressive stress due to a difference in CTE between the two wafers. This, in turn, can result in deformation of the wafers, such as warpage or breakage.

### SUMMARY

Embodiments of the present invention provide a method of bonding wafers, which can effectively minimize wafer deformation due to stress.

Embodiments of the present invention also provide an apparatus for bonding wafers, which can effectively minimize deformation of wafers due to stress.

The above and other objects will be described in or be apparent from the following description of preferred embodiments.

In one aspect, a method of bonding wafers comprises: heating a first wafer having a first coefficient of thermal expansion (CTE) until the first wafer reaches a first temperature; heating a second wafer having a second CTE that is different from the first CTE until the second wafer reaches a second temperature that is different from the second temperature; and bonding the first wafer and the second wafer to each other.

In one embodiment, the heating of the first wafer comprises heating the first wafer from room temperature to the first temperature, wherein the heating of the second wafer comprises heating the second wafer from room temperature to the second temperature, and wherein an increased length of the first wafer is substantially equal to an increased length of the second wafer, the increased length of the first wafer occurring by heating the first wafer from room temperature to the first temperature and the increased length of the second wafer occurringby heating the second wafer from room temperature to the second temperature.

In another embodiment, the bonding of the first wafer and the second wafer further comprises cooling the first wafer and the second wafer to room temperature, wherein a shortened length of the first wafer is substantially equal to a shortened length of the second wafer, the shortened length of the first wafer occurringby cooling the first wafer from first temperature to room temperature and the shortened length of the second wafer occurringby heating the second wafer from the second temperature to room temperature.

In another embodiment, the first CTE is greater than the second CTE and the second temperature is higher than the first temperature.

In another embodiment, the first wafer and the second wafer are bonded to each other so that a to-be-bonded surface of the first wafer faces a to-be-bonded surface of the second wafer, and the to-be-bonded surface of the first wafer has a buffer pattern formed therein.

In another embodiment, the first wafer is a sapphire wafer and the second wafer is a silicon wafer.

In another embodiment, the first wafer has a material layer formed on its first surface, the material layer containing InₓAl_{y}Ga_{(1-x-y)}N, where 0≦x≦1 and 0≦y≦1.

In another aspect, a method of bonding wafers comprises: heating a first wafer having a first CTE to increase a length of the first wafer by a predetermined length; increasing in length a second wafer having a second CTE different from the first CTE by the predetermined length; and bonding the first wafer and the second wafer to each other.

In another aspect, an apparatus for bonding wafers comprises: a first chuck on which a first wafer having a first CTE is mounted; a second chuck on which a second wafer having a second CTE that is different from the first CTE is mounted; an aligner aligning the first wafer and the second wafer with each other; and a temperature controller controlling a temperature of the first chuck to be heated to a third temperature and controlling a temperature of the second chuck to a fourth temperature that is different from the first temperature.

In one embodiment, the first chuck includes a first body containing a first material and a first heating line formed in the first body to heat the first wafer, and the second chuck includes a second body containing a second material and a second heating line formed in the second body to heat the second wafer, and thermal conductivity of the first material is different from that of the second material.

### BRIEF DESCRIPTION OF THE DRAWINGS

The above and other features and advantages will become more apparent by describing in detail preferred embodiments thereof with reference to the attached drawings in which:

FIG. 1 is a graph illustrating temperature-dependent length variations of wafers made of GaN, sapphire, silicon and silicon-aluminum;

FIGS. 2 and 3 illustrate a wafer bonding method according to an exemplary embodiment of the present invention;

FIG. 4 illustrates a wafer bonding method according to another exemplary embodiment of the present invention;

FIGS. 5 through 7 are perspective views of examples of a buffer pattern shown in FIG. 4;

FIGS. 8 and 9 illustrate a wafer bonding method according to another exemplary embodiment of the present invention;

FIG. 10 is a schematic diagram illustrating a wafer bonding apparatus according to exemplary embodiments of the present invention;

FIG. 11 is a schematic diagram illustrating a chuck of the wafer bonding apparatus shown in FIG. 10; and

FIGS. 12A through 13 are schematic cross-sectional views illustrating an aligner of the wafer bonding apparatus shown in FIG. 10.

### DETAILED DESCRIPTION OF EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, and/or sections, these elements, components, and/or sections should not be limited by these terms. These terms are only used to distinguish one element, component or section from another element, component, or section. Thus, a first element, component, or section discussed below could be termed a second element, component, or section without departing from the teachings of the present invention.

Spatially relative terms, such as “below,” “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like numbers refer to like elements throughout.

Exemplary embodiments of the invention are described herein with reference to cross-section illustrations that are schematic illustrations of idealized exemplary embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

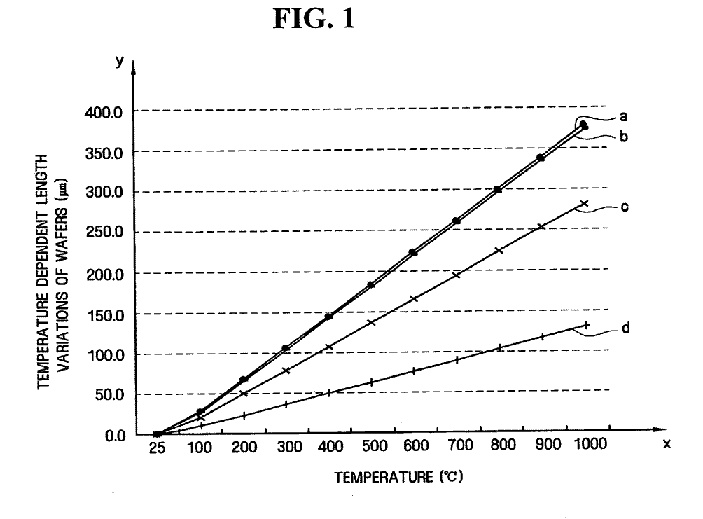

FIG. 1 is a graph illustrating temperature-dependent length variations of wafers made of GaN, sapphire, silicon and silicon-aluminum. Table 1, below, lists experimental data for length variations of wafers in response to a change in the temperature, as shown in FIG. 1.

Referring to FIG. 1, the x-axis of the graph indicates the temperature and the y-axis indicates the temperature-dependent wafer length variations. Reference symbol “a” denotes sapphire, reference symbol “b” denotes silicon-aluminum, reference symbol “c” denotes GaN, and reference symbol “d” denotes silicon, respectively.

Referring to FIG. 1 and Table 1, CTEs of GaN, sapphire, silicon, and silicon-aluminum are 5.60 ppm/K, 7.50 ppm/K, 2.60 ppm/K, 7.40 ppm/K, respectively.

As confirmed from Table 1, sapphire is greatest and silicon is least in terms of CTE.

In the case of using a 2-inch diameter sapphire wafer, for example, when the sapphire wafer is heated from room temperature (about 25 C) to 600 C, the diameter of the sapphire wafer increases by about 219.08 μm. Next, in a case of using a 2-inch silicon wafer, the 2-inch silicon wafer is heated from room temperature (about 25 C) to 600 C, the silicon wafer may have an increased diameter of about 75.95 μm. In other words, the amount of increase in length of the 2-inch sapphire wafer is about three times that of the 2-inch silicon wafer.

TABLE 1

| | | Temperature dependent wafer length variations | | | | |
|---|---|---|---|---|---|---|
| Wafer | CTE | (μm) | | | | |
| material | (ppm/K) | 25 C. | 100 C. | 300 C. | 600 C. | 900 C. |
| GaN | 5.60 | 0 | 21.34 | 78.23 | 163.58 | 248.92 |
| Sapphire | 7.50 | 0 | 28.58 | 104.78 | 219.08 | 333.38 |
| Si | 2.60 | 0 | 9.91 | 36.32 | 75.95 | 115.57 |
| Si—Al | 7.40 | 0 | 28.19 | 103.38 | 216.15 | 328.93 |

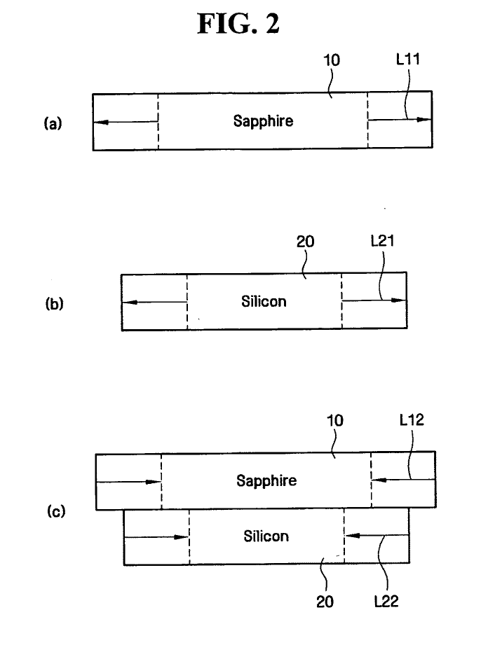

FIGS. 2 and 3 illustrate wafer bonding methods according to exemplary embodiments of the present invention. In detail, FIG. 2 shows that a wafer bonding process is performed after heating two wafers having different CTEs, i.e., a first wafer and a second wafer, to different temperatures, and FIG. 3 shows that a wafer bonding process is performed after heating the first and the second wafer having different CTEs to an identical temperature.

Referring first to FIG. 2, in step (a), the first wafer 10 having a first CTE is heated until the first wafer 10 reaches a first temperature.

In step (b), the second wafer 20 having a second CTE is heated to a second temperature until the second wafer 20 reaches a second temperature. Here, the second CTE is different from the first CTE and the second temperature is different from the first temperature.

The first CTE may be greater than the second CTE. In an exemplary embodiment, the first wafer 10 may be a sapphire wafer and the second wafer 20 may be a silicon wafer. In addition, the second temperature may be higher than the first temperature.

In one embodiment of the present invention, since the second temperature is higher than the first temperature while the first CTE is greater than the second CTE, an increased length L11 of the first wafer 10 may be substantially equal to an increased length L21 of the second wafer 20. The term “substantially equal” is used herein to mean that the increased lengths L11 and L21 can be exactly the same with each other and that the increased lengths L11 and L21 can be slightly different from with each other due to a processing error.

In a specific embodiment, when the first wafer 10, e.g., a sapphire wafer, is heated from room temperature to 100 C, the overall increased length of the first wafer 10 is about 28 μm, as shown in Table 1. Thus, the increased length L11 of the first wafer illustrated in FIG. 2, which is an increased length measured at one end of the wafer, that is, half the overall increased length, may be about 14 μm, (=28/2). By contrast, the overall increased length of the second wafer 20, e.g., a silicon wafer, may not be about 28 μm until the second wafer 20 is heated to 240 C. Thus, the increased length L21 of the second wafer illustrated in FIG. 2 may be 14 μm (=28/2). In other words, the increased lengths L11 and L21 of the first and second wafers 10 and 20 may be substantially the same.

In step (c), bonding is performed on the first wafer 10 heated to the first temperature and the second wafer 20 heated the second temperature. Bonding of the first and second wafers 10 and 20 can be performed according to various well-known techniques. The first and second wafers 10 and 20 may be directly bonded to each other. Alternatively, prior to bonding of the first wafer 10 and the second wafer 20, an adhesive material may be interposed between the first wafer 10 and the second wafer 20.

Next, the first wafer 10 and the second wafer 20 are cooled to room temperature (about 25 C). For example, the first wafer 10 can be cooled from the first temperature to room temperature and the second wafer 20 can be cooled from the second temperature to room temperature.

According to an exemplary embodiment, a shortened length L12, which results from the cooling of the first wafer 10 from the first temperature to room temperature, may be substantially equal to the increased length L11, which results from the heating of the first wafer 10. Similarly, a shortened length L22, which results from the cooling of the second wafer 20 from the second temperature to room temperature, may be substantially equal to the increased length L21, which results from the heating of the second wafer 20. As a result, the shortened lengths L12 and L22 may be substantially the same with each other.

In more detail, when a sapphire wafer is cooled from 100 C to room temperature, the overall shortened length of the sapphire wafer may be about 28 μm. When a silicon wafer is cooled from 240 C to room temperature, the overall shortened length of the silicon wafer may be about 28 μm.

According exemplary embodiments, when the increased lengths L11 and L21 of the first and second wafers 10 and 20 are equal to each other, the shortened lengths L12 and L22 of the first and second wafers 10 and 20 may also be equal to each other. Accordingly, lengths of the first wafer 10 are equal before and after bonding, that is, there is no length variation of the first wafer 10 after bonding and before heating, which holds true for the second wafer 20. Since lengths of the second wafer 20 are equal before and after bonding, there is no length variation of the second wafer 20 after bonding and before heating. As a result, the first and second wafers 10 and 20 can be stable and the influence of tensile stress or compressive stress between the bonded wafers 10, 20 can be mitigated or eliminated.

Although in connection with the embodiment illustrated in FIG. 2 it is described that step (a) is followed by step (b), the sequence of step (a) and step (b) may be reversed or step (a) and step (b) may be performed at the same time.

Referring to the embodiment of FIG. 3, in step (a), a first wafer 110 having a first CTE is heated to a third temperature. In step (b), a second wafer 120 having a second CTE is also heated to the third temperature.

Since the first CTE is greater than the second CTE, an increased length L31 of the first wafer 110 is greater than an increased length L41 of the second wafer 120.

In step (c), bonding is performed between the first wafer 110 heated to the third temperature and the second wafer 120 heated the second temperature.

Then, the first and second wafers 110 and 120 are cooled to room temperature (about 25 C). That is to say, the first and second wafers 110 and 120 are cooled from the third temperature to room temperature.

Since the first wafer 110 is increased by the length L31, the first wafer 110 should be shortened by the length L32 as the result of cooling. Likewise, since the second wafer 120 is increased by the length L41, the second wafer 120 should be shortened by the length L42 as the result of cooling. However, since the first and second wafers 110 and 120 are bonded to each other, the shortened length L32 of the first wafer 110 affects the shortened length L42 of the second wafer 120. For example, in a case where the first wafer 100 has greater hardness than the second wafer 120, the first wafer 110 should be shortened by the length L32 while the second wafer 120 is shortened by a length greater than the shortened length L42. Consequently, after being bonded to the first wafer 110, the second wafer 120 may be placed under compressive stress, as indicated by arrows labeled 130. Accordingly, the bonded first and second wafers 110 and 120 become unstable and thus the bonding may be broken.

As described above, the first and second wafers 10 and 20 having different CTEs are heated to different temperatures and bonded to each other, followed by cooling again, making the bonded first and second wafers 10 and 20 very stable. Accordingly, the bonded first and second wafers 10 and 20 may not be deformed in shape.

Although the invention has been described through the illustrated embodiments shown in FIGS. 2 and 3 with regard to the first wafer 10, 100 using the sapphire wafer by way of example and the second wafer 20, 120 using the silicon wafer by way of example, these embodiments are merely illustrative, and not restrictive of the invention, and other wafer materials apply equally well,

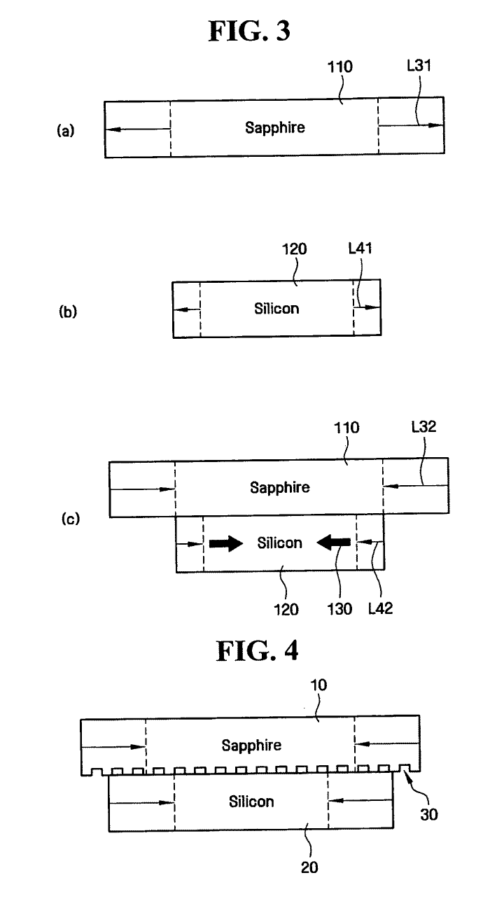

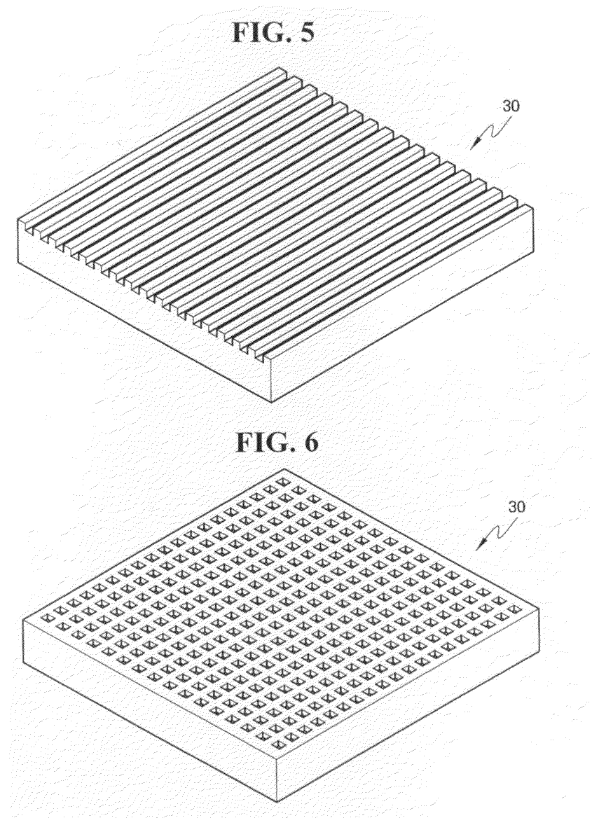

FIG. 4 illustrates a wafer bonding method according to another exemplary embodiment of the present invention, and an explanation about substantially the same processing steps described in FIG. 2 will not be given herein. FIGS. 5 through 7 illustrate examples of a buffer pattern shown in FIG. 4.

Referring to FIG. 4, as described above, a first CTE of the first wafer 10 is greater than a second CTE of the second wafer 20. The first wafer 10 may be a sapphire wafer and the second wafer 20 may be a silicon wafer.

The first wafer 10 and the second wafer 20 are bonded to each other in a state in which a to-be-bonded surface of the first wafer 10 is made to face, or oppose, a to-be-bonded surface of the second wafer 20, and the to-be-bonded surface of the first wafer 10 has a buffer pattern 30 formed therein.

The buffer pattern 30 may effectively reduce the resulting increased length of the to-be-bonded surface of the first wafer 10 as a result of an increase in temperature, thereby reducing stress that may occur between the first wafer 10 and the second wafer 20.

The buffer pattern 30 may be formed by imparting textures to the to-be-bonded surface of the first wafer 10 using, for example, a dicing saw, but embodiments of the invention are not limited to the illustrated example. Alternatively, the buffer pattern 30 may be a line pattern illustrated in FIG. 5, a mesh pattern illustrated in FIG. 6, or a dot pattern illustrated in FIG. 7. However, these patterns are provided for illustration only and the present invention is not limited thereto. Also, the buffer pattern 30 may exceed a predetermined thickness in order to properly perform a buffering function. The thickness of the buffer pattern 30 may vary depending on the materials of the first and second wafers 10 and 20.

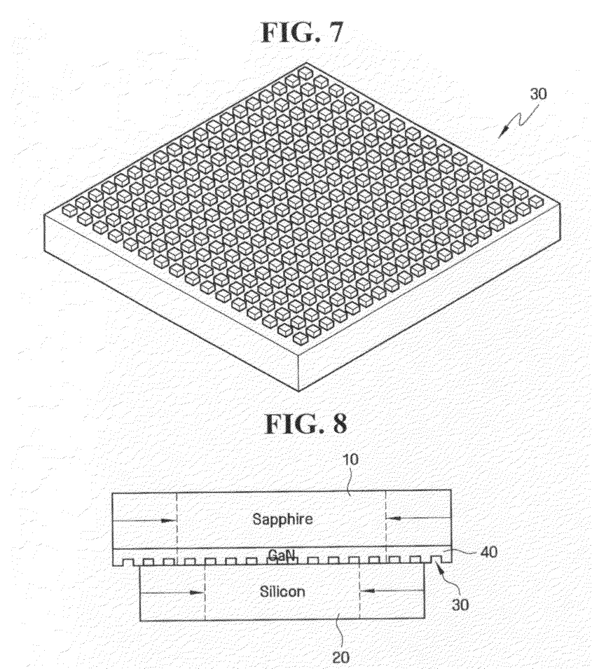

FIGS. 8 and 9 illustrate a wafer bonding method according to still exemplary embodiment of the present invention, and an explanation about substantially the same processing steps described in FIGS. 2 and 4 will not be given herein. The first wafer 10, i.e., a sapphire wafer, may have a material layer 40 formed on its first surface, the material layer 40 containing InₓAl_{y}Ga_{(1-x-y)}N, where 0≦x≦1 and 0≦y≦1.

The first and second wafers 10 and 20 may be bonded such that the material layer 40 is disposed therebetween, as illustrated in FIG. 8. Alternatively, the first wafer 10 may have the material layer 40 formed on its first surface and the first wafer 10 bonded to its second surface, as illustrated in FIG. 9.

The sapphire wafer may be used in fabricating a light emitting device such as a light emitting diode (LED) or a laser diode (LD). In detail, in order to fabricate the light emitting device, the first conductive pattern of a first conductivity type (for example, n-type), a light emitting pattern, and a second conductive pattern of a second conductivity type (for example, p-type) are formed on the sapphire wafer. For example, the first conductive pattern, the light emitting pattern and the second conductive pattern may contain InₓAl_{y}Ga_{(1-x-y)}N (0≦x≦1, 0≦y≦1). In detail, the light emitting pattern corresponds to a light generation region in which carriers in the first conductive pattern (for example, electrons) and carriers in the second conductive pattern (for example, holes) are combined to generate light. The light emitting pattern may be composed of a well layer and a barrier layer. Since the well layer has a smaller band gap than the barrier layer, the carriers (electrons/holes) gather in the well layer to then be combined therein. The light emitting pattern may be classified into a single quantum well (SQW) type; and a multiple quantum well (MQW) type according to the number of well layers included, the former having one well layer and the latter having multiple well layers.

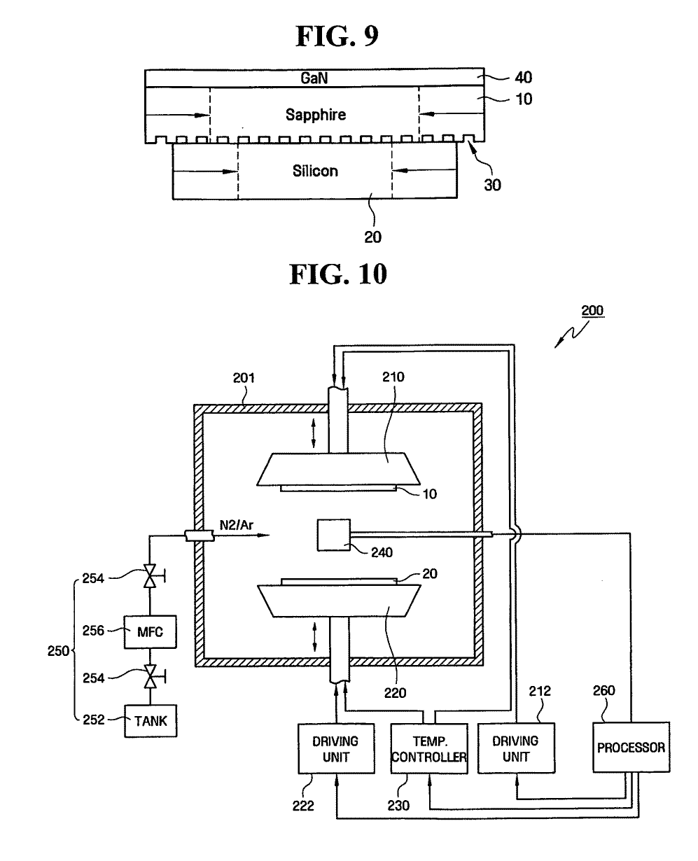

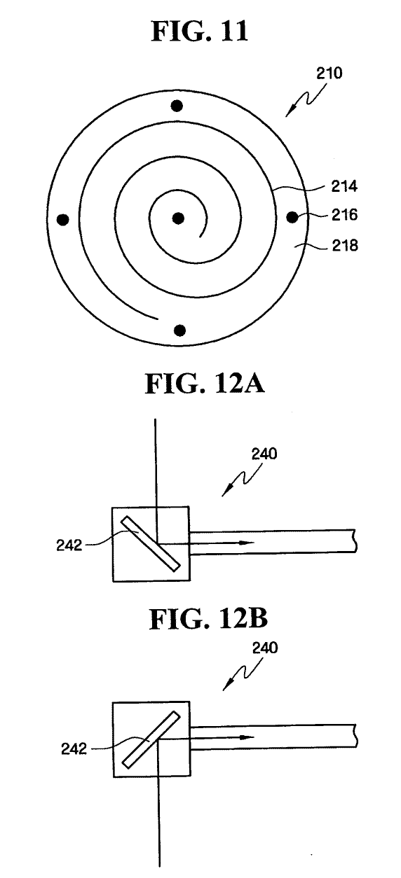

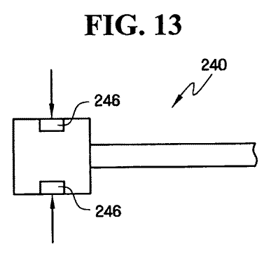

FIG. 10 is a schematic diagram illustrating a wafer bonding apparatus according to exemplary embodiments of the present invention, FIG. 11 is a schematic diagram illustrating a chuck of the wafer bonding apparatus shown in FIG. 10, and FIGS. 12A through 13 are schematic cross-sectional views illustrating an aligner of the wafer bonding apparatus shown in FIG. 10.

Referring to FIG. 10, the wafer bonding apparatus 200 according to exemplary embodiments of the present invention includes a first chuck 210, a second chuck 220, a temperature controller 230, an aligner 240, an inert gas supplier 250, and a processor 260.

The first chuck 210 is installed in a chamber 201 and the first wafer 10 having the first CTE is fixedly mounted thereon. The first chuck 210 may be controlled to be movable by a driving unit 212. The first chuck 210 may have various types, including an electrostatic type, a mechanical type, and so forth. For example, the first chuck 210 may be an electrostatic chuck, as shown in FIG. 11. The first chuck 210 may include a first body 218, a first heating line 214 formed in the first body 218 to heat the first wafer 10, and a vacuum hole 216 for fixing the first wafer 10 by vacuum.

The second chuck 220 is also installed in chamber 201 and the second wafer 20 having the second CTE different from the first CTE is fixedly mounted thereon. The second chuck 220 may be controlled to be movable by a driving unit 222. Although not shown, the second chuck 220 may have substantially the same structure as the first chuck 210. The second chuck 220 may include a second body, a second heating line and a vacuum hole.

The temperature controller 230 may control temperatures of the first chuck 210 and the second chuck 220. In detail, in consideration of CTEs of the first and second wafers 10 and 20, the temperature controller 230 may control the temperature of the first chuck 210 to be a fourth temperature and the temperature of the second chuck 220 to be a fifth temperature that is different than the fourth temperature. The temperature controller 230 may control temperatures of the first chuck 210 and the second chuck 220 by applying biases to the first heating line 214 of the first chuck 210 and the second heating line of the second chuck 220, respectively. As described above, if the first CTE of the first wafer 10 mounted on the first chuck 210 is greater than the second CTE of the second wafer 20 mounted on the second chuck 220, the temperature controller 230 controls the temperature of the second chuck 220 to be higher than that of the first chuck 210.

The aligner 240 aligns the first wafer 10 and the second wafer 20 during bonding. In the aligner 240 provided with a mirror 242, for example, the mirror 242 may be moved to detect a position of the first wafer 10 disposed above the chamber 201, as illustrated in FIG. 12A. The mirror 242 may also be moved to detect a position of the second wafer 20 disposed below the chamber 201, as illustrated in FIG. 12B. In the aligner 240 provided with an image sensor 246, as illustrated in FIG. 13, the image sensor 246 may take pictures the first and second wafers 10 and 20 to detect positions of the first and second wafers 10 and 20.

The inert gas supplier 250 may supply inert gas such as nitrogen (N₂) or argon (Ar) to the chamber 201 for pressure control. The inert gas supplier 250 may include a gas storage tank 252, a valve 254, and a mass flow controller (MFC) 256.

The wafer bonding apparatus 200 according to exemplary embodiments of the present invention may further include an inert gas discharge unit (not shown) through which the inert gas in the chamber 201 is discharged.

Meanwhile, the processor 260 may determine the relative positions of the first and second wafers 10 and 20 using the aligner 240. The processor 260 controls the first driving unit 212 and the second driving unit 222 to adjust the positions of the first and second chucks 210 and 220, thereby allowing the first and second wafers 10 and 20 to be bonded to each other at an appropriate position. The processor 260 may also control the temperature controller 230 to adjust the first and second wafers to reach appropriate temperatures for bonding. Although not shown, the processor 260 may also control the inert gas supplier 250. The processor 260 may also control the inert gas discharge unit.

As described above, the wafer bonding apparatus according to the exemplary embodiments of the present invention independently controls the temperatures of first and second chucks. In other words, the wafer bonding apparatus independently controls the temperatures of the first chuck and the second chuck according to CTEs of the respective wafers mounted to the chucks. In the exemplary embodiments of the present invention, the first chuck includes a first body containing a first material, and the second chuck includes a second body containing a second material, and thermal conductivity of the first material may be different from that of the second material. For example, if the first CTE of the first wafer fixedly mounted on the first chuck is greater than the second CTE of the second wafer fixedly mounted on the second chuck, the thermal conductivity of the first material may be greater than that of the second material. In this case, the temperature control is made such that the temperature of the second chuck is higher than that of the first chuck. Accordingly, in the bonding process, when the first and second wafers are brought into contact with each other to establish an electrical contact therebetween, the temperature of the second chuck may affect the first wafer mounted on the first chuck. That is to say, the temperature of the first wafer may be further increased by a high temperature of the second chuck. To avoid such an unwanted increase of wafer length, it is preferred for the first chuck to be capable of extracting heat transferred from the second chuck. That is to say, the thermal conductivity of the first material may be greater than that of the second material.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A method of bonding wafers comprising:
heating a first wafer having a first coefficient of thermal expansion (CTE) until the first wafer reaches a first temperature;
heating a second wafer having a second CTE that is different from the first CTE until the second wafer reaches a second temperature that is different from the second temperature; and
bonding the first wafer and the second wafer to each other.

2. The method of claim 1, wherein the heating of the first wafer comprises heating the first wafer from room temperature to the first temperature, wherein the heating of the second wafer comprises heating the second wafer from room temperature to the second temperature, and wherein an increased length of the first wafer is substantially equal to an increased length of the second wafer, the increased length of the first wafer occurring by heating the first wafer from room temperature to the first temperature and the increased length of the second wafer occurringby heating the second wafer from room temperature to the second temperature.

3. The method of claim 1, after the bonding of the first wafer and the second wafer, further comprising cooling the first wafer and the second wafer to room temperature,
wherein a shortened length of the first wafer is substantially equal to a shortened length of the second wafer, the shortened length of the first wafer occurringby cooling the first wafer from first temperature to room temperature and the shortened length of the second wafer occurringby heating the second wafer from the second temperature to room temperature.

4. The method of claim 1, wherein the first CTE is greater than the second CTE and the second temperature is higher than the first temperature.

5. The method of claim 4, wherein the first wafer and the second wafer are bonded to each other in a state in which a to-be-bonded surface of the first wafer is made to face a to-be-bonded surface of the second wafer, and the to-be-bonded surface of the first wafer has a buffer pattern formed therein.

6. The method of claim 1, wherein the first wafer is a sapphire wafer and the second wafer is a silicon wafer.

7. The method of claim 6, wherein the first wafer has a material layer formed on its first surface, the material layer containing InₓAl_{y}Ga_{(1-x-y)}N, where 0≦x≦1 and 0≦y≦1.

8. A method of bonding wafers comprising:
heating a first wafer having a first CTE to increase a length of the first wafer by a predetermined length;
increasing in length a second wafer having a second CTE different from the first CTE by the predetermined length; and
bonding the first wafer and the second wafer to each other.

9. (canceled)

10. (canceled)
